(19) United States
(12) Patent Application Publication
(10) Pub. No.: US 2012/0235144 A1
(43) Pub. Date: Sep. 20, 2012

(54) ORGANIC LIGHT EMITTING DIODE DEVICE AND METHOD OF MANUFACTURING THE SAME

(76) Inventors: Ji-Young Choung, Yongin-city (KR); Jin-Baek Choi, Yongin-city (KR); Joon-Gu Lee, Yongin-city (KR); Se-Jin Cho, Yongin-city (KR); Hee-Joo Ko, Yongin-city (KR); Yeon-Hwa Lee, Yongin-city (KR); Won-Jong Kim, Yongin-city (KR); Young-Woo Song, Yongin-city (KR); Jong-Hyuk Lee, Yongin-city (KR)

(21) Appl. No.: 13/207,218

(22) Filed: Aug. 10, 2011

(30) Foreign Application Priority Data
Mar. 18, 2011 (KR) 10-2011-0024137

(51) Int. Cl. H01L 33/36; H01L 33/40; H01L 33/16

(52) U.S. Cl. 257/57; 257/66; 438/22; 257/E33.053; 257/E33.064

(57) ABSTRACT

An organic light emitting diode device includes a substrate, a thin film transistor on the substrate, a first pixel electrode electrically connected to the thin film transistor, a pixel defining layer on the first pixel electrode and partitioning a light emitting region, a second pixel electrode contacting the first pixel electrode at the light emitting region, a light emitting layer contacting the second pixel electrode at the light emitting region, and a common electrode on the light emitting layer; and a method of manufacturing the same is provided.

### CROSS-REFERENCE TO RELATED APPLICATION

This application claims priority to and the benefit of Korean Patent Application No. 10-2011-0024137 filed in the Korean Intellectual Property Office on Mar. 18, 2011, the entire content of which is incorporated herein by reference.

### BACKGROUND

1. Field

Aspects of embodiments according to the present invention relate to an organic light emitting diode device and a method of manufacturing the same.

2. Description of the Related Art

Recently, an organic light emitting diode (OLED) device has been used in a display device and an illumination device.

An organic light emitting diode device in general includes two electrodes and an emission layer disposed therebetween, and emits light when electrons injected from one electrode are combined with holes injected from the other electrode and thus form excitons and emit energy.

One electrode (hereinafter, referred as “pixel electrode”) of the two electrodes may be disposed in each pixel to be independently driven.

A pixel defining layer may be formed between the pixel electrode and the emission layer. The pixel defining layer electrically insulates the adjacent pixel electrodes and defines the light emitting region.

### SUMMARY

The pixel defining layer may be formed of an organic material, and it may be obtained by, for example, coating and patterning an organic layer on the pixel electrode. In this case, an organic residue may remain on the pixel electrode after forming the pixel defining layer. The organic residue may cause the deterioration of display characteristics such as image sticking.

In addition, a plasma process using oxygen gas and nitrogen gas may be further performed in order to remove the organic residue, but the additional plasma process may affect the electric characteristics of a conductive oxide of the pixel electrode due to the oxygen gas and nitrogen gas.

An aspect of the present invention is directed toward a simplified process for fabricating an organic light emitting diode device with improved characteristics such as electric characteristics.

Another aspect of the present invention is directed toward a method of manufacturing the organic light emitting diode device.

According to an embodiment, an organic light emitting diode device includes a substrate, a thin film transistor on the substrate, a first pixel electrode electrically connected with the thin film transistor, a pixel defining layer for partitioning a light emitting region on the first pixel electrode, a second pixel electrode contacting the first pixel electrode at the light emitting region, a light emitting layer contacting the second pixel electrode at the light emitting region, and a common electrode on the light emitting layer.

The second pixel electrode may include a conductive oxide.

The second pixel electrode may include a material selected from the group consisting of indium tin oxide (ITO), indium zinc oxide (IZO), aluminum doped zinc oxide (AZO), indium gallium zinc oxide (IGZO), and combinations thereof.

The second pixel electrode may have a work function between about 4.5 eV and about 6.0 eV.

The second pixel electrode may include a same material as the first pixel electrode.

The second pixel electrode may have a thickness between about 10 Å and about 200 Å.

The pixel defining layer may include an organic material, and the organic material may not be present between the second pixel electrode and the light emitting layer.

The first pixel electrode may include a reflective layer and an auxiliary layer positioned above or below the reflective layer.

According to another embodiment of the present invention, a method of manufacturing the organic light emitting diode device includes forming a thin film transistor on a substrate; forming a first pixel electrode electrically connected with the thin film transistor, forming a pixel defining layer partitioning a light emitting region on the first pixel electrode; forming a second pixel electrode contacting the first pixel electrode at the light emitting region; forming a light emitting layer contacting the second pixel electrode at the light emitting region; and forming a common electrode on the light emitting layer.

The forming of the pixel defining layer may include forming an organic layer on the first pixel electrode; and patterning the organic layer to partition the light emitting region, thereby exposing the first pixel electrode.

The second pixel electrode may include a conductive oxide having a work function between about 4.5 eV and about 6.0 eV.

The second pixel electrode may include a same material as the first pixel electrode.

A plasma process may be not performed before forming the light emitting layer.

According to the embodiments of the present invention, deterioration of the display characteristics, such as image sticking due to the presence of the organic residue, may be prevented or reduced by avoiding the formation of the organic residue between the pixel electrode and the organic light emitting layer. Further, the application of the oxygen plasma for removing the organic residue may be avoided, and therefore the degeneration of the electric characteristic of the conductive oxide and the deterioration of the life-span due to the image sticking may be prevented.

### BRIEF DESCRIPTION OF THE DRAWINGS

FIG. 1 is a cross-sectional view showing an organic light emitting diode device according to one embodiment.

FIG. 2 is a cross-sectional view showing an organic light emitting diode device according to another embodiment.

FIG. 3 is a graph showing the results of measuring the electrode surface obtained from Example 1 and Comparative Example 1 by the photoelectron spectrometry (XPS).

FIG. 4 is a graph showing luminance change of an organic light emitting diode device obtained from Example 2 and Comparative Example 2 with respect to time.

### DETAILED DESCRIPTION

The present disclosure will be described more fully hereinafter with reference to the accompanying drawings, in which exemplary embodiments of the present invention are shown. The present invention may, however, be embodied in many different forms and should not be construed as limited to the exemplary embodiments set forth herein.

In the drawings, the thicknesses of layers, films, panels, regions, etc., are exaggerated for clarity. Like reference numerals designate like elements throughout the specification. It will be understood that when an element such as a layer, film, region, or substrate is referred to as being “on” another element, it may be directly on the other element, or one or more intervening elements may also be present.

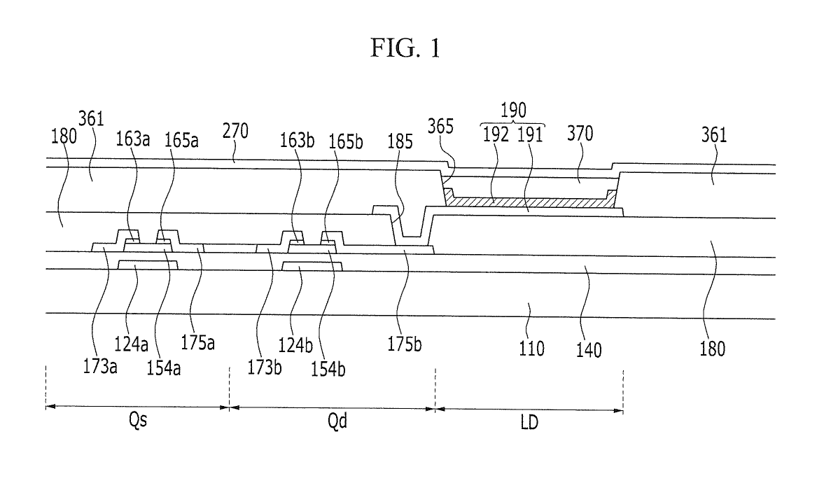

Referring to FIG. 1, an organic light emitting diode device will be described in accordance with an embodiment of the present invention.

FIG. 1 is a cross-sectional view of an organic light emitting diode device according to one embodiment.

The organic light emitting diode device according to one embodiment includes a switching transistor region (Qs) including a switching thin film transistor; a driving transistor region (Qd) including a driving thin film transistor; and a light emitting region (LD) including an organic light emitting diode (OLED) in each pixel.

The switching thin film transistor includes a control terminal, an input terminal, and an output terminal. The control terminal is connected to a gate line (not shown); the input terminal is connected to a data line (not shown); and the output terminal is connected to the driving thin film transistor. The switching thin film transistor responds to a scan signal applied to the gate line and transfers a data signal applied to the data line to the driving thin film transistor.

The driving thin film transistor also includes a control terminal, an input terminal, and an output terminal. The control terminal is connected to the switching thin film transistor; the input terminal is connected to a driving voltage line (not shown); and the output terminal is connected to an organic light emitting diode (OLED). The driving thin film transistor supplies an output current which has a magnitude depending upon the voltage between the control terminal and the output terminal of the driving thin film transistor.

The organic light emitting diode (OLED) includes an anode connected to the output terminal of the driving thin film transistor and a cathode connected to a common voltage (e.g., a ground voltage). The organic light emitting diode (OLED) emits light having a luminance in accordance with the output current supplied by the driving thin film transistor in order to display images.

Referring to FIG. 1, a switching control electrode 124a and a driving control electrode 124b are formed on a substrate 110 made of glass, polymer layer, silicon wafer, or the like.

The switching control electrode 124a is connected to a gate line (not shown) and receives a gate signal from the gate line.

The driving control electrode 124b has an island shape.

A gate insulating layer 140 is formed on the switching control electrode 124a and the driving control electrode 124b.

A switching semiconductor layer 154a and a driving semiconductor layer 154b are formed on the gate insulating layer 140.

The switching semiconductor layer 154a is overlapped with the switching control electrode 124a, and the driving semiconductor layer 154b is overlapped with the driving control electrode 124b.

The switching semiconductor layer 154a and the driving semiconductor layer 154b may each have an island shape, and may be made of an inorganic semiconductor material such as hydrogenated amorphous silicon or polysilicon or an organic semiconductor material.

A switching input electrode 173a and a switching output electrode 175a connected to the switching semiconductor layer 154a are at least partially formed on the switching semiconductor layer 154a.

The switching input electrode 173a is connected to the data line (not shown) and receives the data signal from the data line.

The switching output electrode 175a is connected to the following driving control electrode 124b.

A driving input electrode 173b and a driving output electrode 175b electrically connected to the driving semiconductor layer 154b are each formed at least partially on the driving semiconductor layer 154b.

The driving input electrode 173b is connected to the driving voltage line (not shown).

The driving output electrode 175b is connected to the following first pixel electrode 191.

Ohmic contact members (163a, 165a, 163b, and 165b) are respectively formed between the switching semiconductor layer 154a and the switching input electrode 173a, between the switching semiconductor layer 154a and the switching output electrode 175a, between the driving semiconductor layer 154b and the driving input electrode 175b, and between the driving semiconductor layer 154b and the driving output electrode 175b.

A protective layer 180 is formed on the switching input electrode 173a, the switching output electrode 175a, the driving input electrode 173b, and the driving output electrode 175b.

The protective layer 180 has a contact hole 185 exposing the driving output electrode 175b.

The first pixel electrode 191 is formed on the protective layer 180.

The first pixel electrode 191 is connected to the driving output electrode 175b through the contact hole 185.

The first pixel electrode 191 may be made of conductive oxide, for example, indium tin oxide (ITO), indium zinc oxide (IZO), aluminum doped zinc oxide (AZO), indium gallium zinc oxide (IGZO), or combinations thereof.

The first pixel electrode 191 may have a work function of about 4.5 to 6.0 eV in accordance with the energy level of a light emitting member 370 (e.g., a light emitting layer).

A pixel defining layer 361 is formed on the first pixel electrode 191.

The pixel defining layer 361 has an opening 365 exposing the first pixel electrode 191, and the opening 365 of the pixel defining layer 361 defines the light emitting region LD.

The pixel defining layer 361 may be made of, for example, a photosensitive organic material.

A second pixel electrode 192 is formed in the light emitting region LD surrounded by the pixel defining layer 361.

The second pixel electrode 192 is connected to the first pixel electrode 191 in the light emitting region LD.

The second pixel electrode 192 covers the surface of the first pixel electrode 191 after forming the pixel defining layer 361, so that it may prevent the organic residue remaining on the surface of the first pixel electrode 191 from affecting the organic light emitting member 370.

For example, the pixel defining layer 361 is prepared by providing an organic layer on the front surface including the first pixel electrode 191; and patterning the organic layer to provide an opening 365 exposing the first pixel electrode 191. Even if the portion of the organic layer formed on the first pixel electrode 191 is removed, the organic residue may remain on the surface of first pixel electrode 191, and the organic residue may remain between the pixel electrode 190 and the organic light emitting member 370. Thereby, it may affect the display characteristic and the electric characteristic of the organic light emitting diode device.

According to one embodiment, the second pixel electrode 192 covering the first pixel electrode 191 is formed in the light emitting region LD after forming the pixel defining layer 361, so that it may prevent the organic residue from remaining between the pixel electrode 190 and the organic light emitting member 370. Thereby, it may prevent the display characteristic and the electric characteristic of the organic light emitting diode device from being affected due to the organic residue that is present between the pixel electrode 190 and the organic light emitting member 370 in the light emitting region.

The second pixel electrode 192 may be made of the same material as the first pixel electrode 191.

The second pixel electrode 192 may be made of a conductive oxide, for example, indium tin oxide (ITO), indium zinc oxide (IZO), aluminum doped zinc oxide (AZO), indium gallium zinc oxide (IGZO), or combinations thereof.

The second pixel electrode 192 may have a work function of about 4.5 to 6.0 eV in accordance with an energy level of the organic light emitting member 370.

The second pixel electrode 192 may have a thickness between about 10 Å and 200 Å.

The organic light emitting member 370 is formed on the second pixel electrode 192.

The organic light emitting member 370 includes an emission layer and an auxiliary layer.

The emission layer may be made of an organic material that emits light such as red light, green light, blue light, or the like, and it may express white color by a combination of these colors.

The auxiliary layer may be disposed above and/or below the emission layer, and may include a hole injection layer (HIL), a hole transport layer, an electron injection layer (EIL), and/or an electron transport layer.

A common electrode 270 is formed on the pixel defining layer 361 and the organic light emitting member 370. The common electrode 270 may be formed of a transparent metal or a high-reflective metal.

In the organic light emitting diode device, the pixel electrode 190 or the common electrode 270 may be an anode, and the other may be a cathode. The anode may be paired with the cathode to supply current to the organic light emitting member 370.

The method of manufacturing the organic light emitting diode device is described with reference to FIG. 1.

First, a conductive layer is laminated on the substrate 110 and patterned to provide the switching control electrode 124a and the driving control electrode 124b.

The gate insulating layer 140 is formed on the switching control electrode 124a and the driving control electrode 124b.

Then the switching semiconductor layer 154a, which is overlapped with the switching control electrode 124a, and the driving semiconductor layer 154b, which is overlapped with the driving control electrode 124b, are formed on the gate insulating layer 140.

The ohmic contact members (163a, 165a, 163b, and 165b) are respectively formed on the switching semiconductor layer 154a and the driving semiconductor layer 154b.

A conductive layer is stacked on the ohmic contact members (163a, 165a, 163b, and 165b) and patterned to provide the switching input electrode 173a, the switching output electrode 175a, the driving input electrode 173b, and the driving output electrode 175b.

The protective layer 180 is formed on the switching input electrode 173a, the switching output electrode 175a, the driving input electrode 173b, and the driving output electrode 175b.

The protective layer 180 is patterned to provide the contact hole 185, thereby exposing the output electrode 175b.

A conductive oxide layer is stacked on the protective layer 180 and patterned to provide the first pixel electrode 191.

The pixel defining layer 361 is formed on the first pixel electrode 191.

The pixel defining layer 361 maybe prepared by coating an organic layer and patterning the organic layer to provide an opening 365, thereby exposing the first pixel electrode 191.

Then, a conductive oxide layer is stacked on the first pixel electrode 191 and the pixel defining layer 361, and is patterned to provide the second pixel electrode 192 that is in contact with the first pixel electrode 191 at the light emitting region LD.

The organic light emitting member 370 is formed on the second pixel electrode 192.

The common electrode 270 is formed on the pixel defining layer 361 and the organic light emitting member 370.

According to one embodiment, the second pixel electrode 192 is formed after providing the pixel defining layer 361, so that the additional plasma process for removing the organic residue on the lower layer, which is the surface of the pixel electrode 190, is not required before providing the organic light emitting member 370. Thereby, the process may be simplified.

In addition, if the plasma process is performed on the surface of the pixel electrode 190, the electric characteristics would be affected by changing the composition of conductive oxide for the pixel electrode. However, according to one embodiment, the electrical characteristic deterioration of the organic light emitting diode device may be prevented by not performing the plasma process.

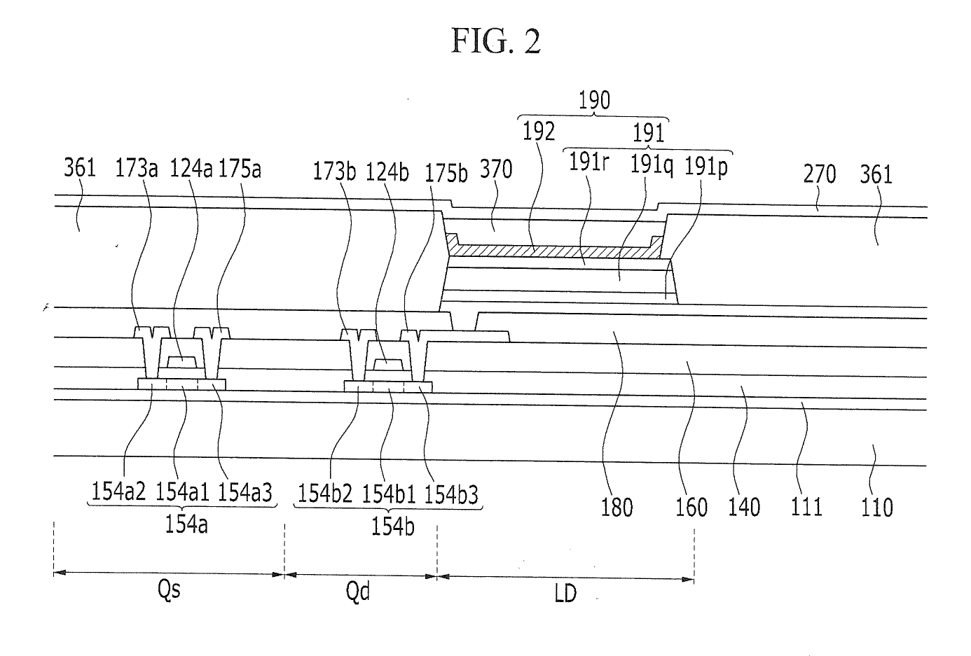

The organic light emitting diode device according to another embodiment is described with reference to FIG. 2.

FIG. 2 is a cross-sectional view showing the organic light emitting diode device according to another embodiment.

Referring to FIG. 2, a buffer layer 111 is formed on a substrate made of, for example, glass, polymer layer, or silicon wafer or the like.

The buffer layer 111 may be made of, for example, silicon oxide or nitrogen oxide or the like, and it may prevent the transfer of moisture or impurities generated from the transparent substrate 110 to the upper layer and control the thermal transfer speed during the process of crystallizing the semiconductor layer to increase the crystallinity.

A switching semiconductor layer 154a and a driving semiconductor layer 154b are formed at the switching transistor region Qs and the driving transistor region Qd, respectively, on the buffer layer 111. The switching semiconductor layer 154a and the driving semiconductor layer 154b each include a source region (154a2, 154b2) and a drain region (154a3, 154b3) disposed on opposite sides of a channel region (154a1, 154b1), respectively.

The switching semiconductor layer 154a and the driving semiconductor layer 154b may include polycrystaline semiconductor, and the source regions (154a2, 154b2) and the drain regions (154a3, 154b3) are doped with n-type or p-type impurities.

A gate insulating layer 140 is formed on the switching semiconductor layer 154a and the driving semiconductor layer 154b.

A switching control electrode 124a and a driving control electrode 124b are formed on the gate insulating layer 140.

The switching control electrode 124a is overlapped with the switching semiconductor layer 154a; and the driving control electrode 124b is overlapped with the driving semiconductor layer 154b.

An insulation layer 160 is formed on the switching control electrode 124a and the driving control electrode 124b. The insulation layer 160 and the gate insulating layer 140 have a plurality of contact holes exposing the source regions (154a2, 154b2) and the drain regions (154a3, 154b3) of the switching semiconductor layer 154a and the driving semiconductor layer 154b.

On the insulation layer 160, a switching input electrode 173a and a switching output electrode 175a are formed at the switching transistor region Qs, and a driving input electrode 173b and a driving output electrode 175b are formed at the driving transistor region Qd.

The switching input electrode 173a and the switching output electrode 175a are connected to the source region 154a2 and the drain region 154a3 of the switching semiconductor layer 154a, respectively, through contact holes. The driving input electrode 173b and the driving output electrode 175b are connected to the source region 154b2 and the drain region 154b3 of the driving semiconductor layer 154b, respectively, through contact holes.

A protective layer 180 is formed on the switching input electrode 173a, the switching output electrode 175a, the driving input electrode 173b, and the driving output electrode 175b.

The protective layer 180 has a contact hole 185 exposing the driving output electrode 175b.

A first pixel electrode 191 is formed on the protective layer 180.

The first pixel electrode 191 includes a lower auxiliary layer 191p, a reflective layer 191q, and an upper auxiliary layer 191r.

The reflective layer 191q may be made of an opaque metal such as aluminum (Al), copper (Cu), silver (Ag), or an alloy thereof. For example, it may be made of an aluminum-palladium-copper alloy (Al—Pd—Cu alloy).

The lower auxiliary layer 191p and the upper auxiliary layer 191r may improve the adherence with the lower layer and protect the reflective layer 191q, and it may be made of, for example, indium tin oxide (ITO), indium zinc oxide (IZO), aluminum doped zinc oxide (AZO), indium gallium zinc oxide (IGZO), or combinations thereof.

At least one of the lower auxiliary layer 191p and upper auxiliary layer 191r may be omitted.

A pixel defining layer 361 is formed on the first pixel electrode 191.

The pixel defining layer 361 has an opening 365 exposing the first pixel electrode 191, and the opening 365 of the pixel defining layer 361 defines a light emitting region LD.

A second pixel electrode 192 is formed at the light emitting region LD that is defined by the opening 365 of the pixel defining layer 361.

The second pixel electrode 192 is in contact with the first pixel electrode 191 at the light emitting region LD.

The second pixel electrode 192 covers the surface of the first pixel electrode 191 after forming the pixel defining layer 361, so that an organic residue remaining on the surface of the first pixel electrode 191 may be prevented from affecting the organic light emitting member 370.

The second pixel electrode 192 may be made of the same material as in the upper auxiliary layer 191 r of the first pixel electrode 191.

The second pixel electrode 192 may be made of conductive oxide, for example, indium tin oxide (ITO), indium zinc oxide (IZO), aluminum doped zinc oxide (AZO), indium gallium zinc oxide (IGZO), or combinations thereof.

The second pixel electrode 192 may have a work function between about 4.5 eV and 6.0 eV in accordance with an energy level of the organic light emitting member 370.

The second pixel electrode 192 may have a thickness between about 10 Å to 200 Å.

An organic light emitting member 370 is formed on the second pixel electrode 192.

The organic light emitting member 370 includes an emission layer and an auxiliary layer.

The emission layer may be made of organic materials that emit light such as red light, green light, blue light, or the like, and it may express white color by a combination of these colors.

The auxiliary layer may be disposed to be above or below the emission layer, and it may be a hole injection layer (HIL), a hole transport layer, an electron injection layer (EIL), and/or an electron transport layer.

A common electrode 270 is formed on the pixel defining layer 361 and the organic light emitting member 370. The common electrode 270 may be made of a transparent or translucent conductor.

The pixel electrode 190 and the common electrode 270 may form a microcavity. The microcavity amplifies light having a set or predetermined wavelength due to the constructive interference by repeatedly reflecting light in the optical length between the reflective layer and the transparent (or translucent) layer that are spaced from each other.

According to one embodiment, the pixel electrode 190 may act as a reflective layer, and the common electrode 270 may act as a transparent (or translucent) layer, and the optical path length may be controlled by changing the distance between the pixel electrode 190 and the common electrode 270 in each pixel.

The pixel electrode 190 significantly modifies the characteristics of the light emitting from the organic emission layer 370, and the light having the wavelength around the resonant wavelength of the microcavity is reinforced (or enhanced) through the common electrode 270 and emitted to the outside, and light having other wavelengths may be suppressed.

The organic light emitting diode device according to this embodiment includes a pixel electrode 190 that is a reflecting electrode and a common electrode 270 that is a transparent electrode, so it has a top emission structure such that light emitted from the emission layer 370 is emitted to the opposite side of the substrate 110.

The method of manufacturing the organic light emitting diode device is described with reference to FIG. 2.

First, the buffer layer 111 is formed on the substrate 110 by chemical vapor deposition (CVD).

Then, an amorphous silicon layer is deposited on the buffer layer 111 and is crystallized by chemical vapor deposition (CVD) or physical vapor deposition (PVD). The crystallization may be performed by, for example, excimer laser annealing (ELA), sequential lateral solidification (SLS), metal induced crystallization (MIC), metal induced lateral crystallization (MILC), super grain silicon (SGS), or the like.

Then, the crystallized semiconductor layer is patterned to provide the switching semiconductor layer 154a and the driving semiconductor layer 154b.

The gate insulating layer 140 is formed on the front surface of the substrate including the switching semiconductor layer 154a and the driving semiconductor layer 154b.

A conductive layer is stacked on the gate insulating layer 140 and is patterned to provide the switching control electrode 124a that is overlapped with the switching semiconductor layer 154a and the driving control electrode 124b that is overlapped with the driving semiconductor layer 154b.

The insulation layer 160 is formed on the switching control electrode 124a and the driving control electrode 124b.

The insulation layer 160 and the gate insulating layer 140 are patterned to provide a plurality of contact holes.

The conductive layer is stacked on the insulation layer 160 and is patterned to provide a switching input electrode 173a, a switching output electrode 175a, a driving input electrode 173b, and a driving output electrode 175b.

The protective layer 180 is formed on the switching input electrode 173a, the switching output electrode 175a, the driving input electrode 173b, and the driving output electrode 175b.

The protective layer 180 is patterned to provide the contact hole 185.

Then, conductive layers are sequentially stacked on the protective layer and are patterned to provide the first pixel electrode 191 including the lower auxiliary layer 191p, the reflective layer 191q, and the upper auxiliary layer 191r.

The pixel defining layer 361 is formed on the first pixel electrode 191.

An organic layer is coated on the pixel defining layer 361 and is patterned to provide the opening 365 exposing the first pixel electrode 191.

Then, a conductive oxide layer is stacked on the first pixel electrode 191 and the pixel defining layer 361, and is patterned to provide the second pixel electrode 192 that is in contact with the first pixel electrode 191 at the light emitting region LD.

Then, the organic light emitting member 370 is formed on the second pixel electrode 192.

The common electrode 270 is formed on the pixel defining layer 361 and the organic light emitting member 370.

As described above, since the second pixel electrode 192 is provided after providing the pixel defining layer 361, the additional plasma process is not used to remove the organic residue on the lower layer, which is the surface of the pixel electrode 190, before forming the organic emitting member 370. Accordingly, the fabrication process may be simplified.

In addition, if the plasma process were performed on the surface of the pixel electrode 190, the composition of the conductive oxide of the pixel electrode would be changed to affect the electric characteristics of the pixel electrode. However, according to this embodiment, the electric characteristic deformation of the organic light emitting diode device may be prevented by not performing the plasma process.

The following examples illustrate the present invention in more detail. These examples, however, are not in any sense to be interpreted as limiting the scope of the present invention.

### EXAMPLE 1

An indium tin oxide (ITO) layer is stacked in a thickness of about 70 Å and is patterned to provide a lower conductive layer. Then, an insulation layer for a pixel defining layer is coated on the lower conductive layer in a thickness of about 1 μm and is patterned to provide a pixel defining layer exposing the lower conductive layer. Another indium tin oxide (ITO) layer is stacked and patterned to provide an electrode as an upper conductive layer that is sequentially stacked on the lower conductive layer.

### COMPARATIVE EXAMPLE 1

An indium tin oxide (ITO) layer is stacked on a glass substrate in a thickness of about 70 Å and is patterned to provide an electrode of a lower conductive layer. An insulation layer for a pixel defining layer is coated on the lower conductive layer in a thickness of about 1 μm and is patterned to provide a pixel defining layer exposing the lower conductive layer.

### Evaluation—1

The chemical bond of oxygen on the surface of the electrode obtained from Example 1 and Comparative Example 1 is measured according to x-ray photoelectron spectroscopy (XPS).

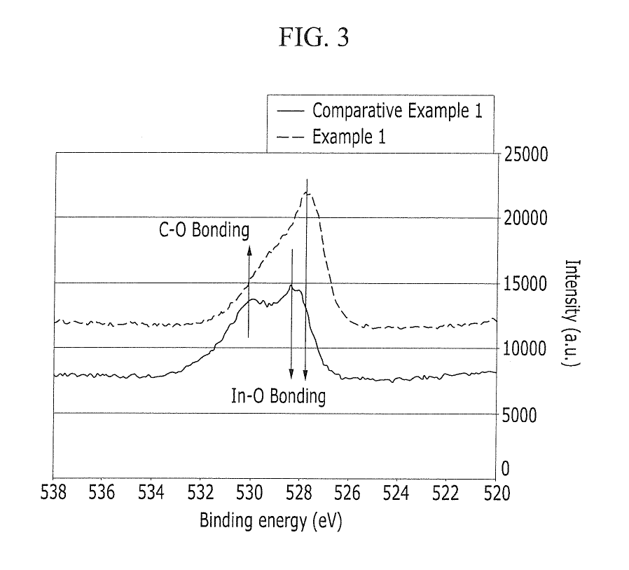

FIG. 3 shows a graph showing the results of measuring the electrode surface obtained from Example 1 and Comparative Example 1 according to x-ray photoelectron spectroscopy (XPS).

Referring to FIG. 3, it is shown that only indium-oxygen bonding (In—O bonding) of indium tin oxide (ITO) is observed on the electrode surface according to Example 1; on the other hand, carbon-oxygen bonding (C—O bonding) of an organic residue remained on the electrode surface during the formation of a pixel defining layer is also observed on the electrode surface according to Comparative Example 1, as well as indium-oxygen bonding (In—O bonding) of indium tin oxide (ITO). Accordingly, it is understood that the organic residue is not observed on the electrode surface according to Example 1, but the organic residue is observed on the electrode surface according to Comparative Example 1.

### EXAMPLE 2

A thin film transistor is fabricated according to the same procedure as in the above-mentioned embodiment. An indium tin oxide (ITO) layer is stacked in a thickness of about 70 Å and is patterned to provide a lower conductive layer. An insulation layer for a pixel defining layer is coated on the lower conductive layer in a thickness of about 1 μm and is patterned to provide a pixel defining layer, thereby exposing the lower conductive layer. An indium tin oxide (ITO) layer is stacked and patterned to provide an electrode as the upper conductive layer that is sequentially stacked on the lower conductive layer. HIL/HTL layers (common organic layers) are stacked on the electrode in a thickness of about 1350 Å, and, for example, a layer of Blue EML in a thickness of 200 Å, a layer of METL in a thickness of 350 Å, and a layer of Mg—Ag are stacked on the front surface (or top surface) to provide an organic light emitting diode device.

### COMPARATIVE EXAMPLE 2

An organic light emitting diode device is fabricated in accordance with the same procedure as in Example 2, except that the upper conductive layer is not provided.

### Evaluation—2

The life-span showing the image sticking in the organic light emitting diode devices obtained from Example 2 and Comparative Example 2 is measured. The life-span showing the image sticking is measured at a room temperature (about 25° C.) under the general atmosphere and is defined by the time of decreasing the luminance to about 97% with respect to the initial value.

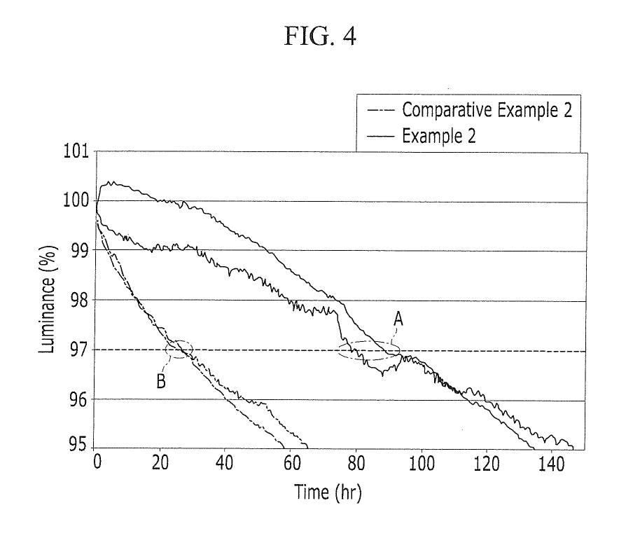

FIG. 4 is a graph showing the luminance change of organic light emitting diode devices obtained from Example 2 and Comparative Example 2 with respect to time.

Referring to FIG. 4, it is understood that the time of decreasing the luminance to about 97% with respect to the initial value is about 80 to 90 hours (A) in the organic light emitting diode device obtained from Example 2; on the other hand, the time of decreasing the luminance to about 97% with respect to the initial value is about 25 to 30 hours (B) in the organic light emitting diode device obtained from Comparative Example 2. From the results, it is shown that the organic light emitting diode device obtained from Example 2 significantly improves the life-span showing image sticking in comparison to the organic light emitting diode device obtained from Comparative Example 2.

While the present invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims, and equivalents thereof.

### DESCRIPTION OF SYMBOLS

| | |
|---|---|
| 110: substrate | 111: buffer layer |
| 124a: switching control electrode | 124b: driving control electrode |
| 140: gate insulating layer | 154a: switching semiconductor |
| 154b: driving semiconductor | 160: insulation layer |
| 180: protective layer | 190: pixel electrode |
| 191: first pixel electrode | 192: second pixel electrode |
| 270: common electrode | 361: pixel defined layer |
| 370: organic emission member | |

What is claimed is:

1. An organic light emitting diode device comprising:
a substrate;
a thin film transistor on the substrate;
a first pixel electrode electrically connected to the thin film transistor;
a pixel defining layer on the first pixel electrode, and partitioning a light emitting region;
a second pixel electrode contacting the first pixel electrode at the light emitting region;
a light emitting layer contacting the second pixel electrode at the light emitting region; and
a common electrode on the light emitting layer.

2. The organic light emitting diode device of claim 1, wherein the second pixel electrode comprises a conductive oxide.

3. The organic light emitting diode device of claim 2, wherein the second pixel electrode comprises a material selected from the group consisting of indium tin oxide (ITO), indium zinc oxide (IZO), aluminum doped zinc oxide (AZO), indium gallium zinc oxide (IGZO), and combinations thereof.

4. The organic light emitting diode device of claim 1, wherein the second pixel electrode has a work function between about 4.5 eV and about 6.0 eV.

5. The organic light emitting diode device of claim 1, wherein the second pixel electrode comprises a same material as the first pixel electrode.

6. The organic light emitting diode device of claim 1, wherein the second pixel electrode has a thickness between about 10 Å and about 200 Å.

7. The organic light emitting diode device of claim 1, wherein the pixel defining layer comprises an organic material, and
the organic material is not present between the second pixel electrode and the light emitting layer.

8. The organic light emitting diode device of claim 1, wherein the first pixel electrode comprises
a reflective layer, and
an auxiliary layer located above or below the reflective layer.

9. A method of manufacturing an organic light emitting diode device comprising:
forming a thin film transistor on a substrate;
forming a first pixel electrode electrically connected to the thin film transistor;
forming a pixel defining layer partitioning a light emitting region on the first pixel electrode;
forming a second pixel electrode contacting the first pixel electrode at the light emitting region;
forming a light emitting layer contacting the second pixel electrode at the light emitting region; and
forming a common electrode on the light emitting layer.

10. The method of claim 9, wherein the forming of the pixel defining layer comprises:
forming an organic layer on the first pixel electrode, and
patterning the organic layer to partition the light emitting region, thereby exposing the first pixel electrode.

11. The method of claim 9, wherein the second pixel electrode comprises a conductive oxide having a work function between about 4.5 eV and about 6.0 eV.

12. The method of claim 9, wherein the second pixel electrode comprises a same material as the first pixel electrode.

13. The method of claim 9, wherein a plasma process is not performed before forming the light emitting layer.
